(19) United States
(12) Patent Application Publication
(10) Pub. No.: US 2024/0372359 A1
(43) Pub. Date: Nov. 7, 2024

(54) DEVICE FOR PROTECTION AGAINST ELECTROSTATIC DISCHARGES

(71) Applicant: STMicroelectronics International N.V., Geneva (CH)

(72) Inventors: Jérôme HEURTIER, Tours (FR); Fabrice GUITTON, Monnaie (FR); Eric LACONDE, Tours (FR)

(73) Assignee: STMicroelectronics International N.V., Geneva (CH)

(21) Appl. No.: 18/642,513

(22) Filed: Apr. 22, 2024

(30) Foreign Application Priority Data
May 4, 2023 (FR) 2304475

(51) Int. Cl. H02H 9/04

(52) U.S. Cl. CPC H02H 9/046

(57) ABSTRACT

The present description concerns a device of protection against electrostatic discharges including: at least one first rectifying element including an anode connected to a first terminal and a cathode connected to a first node of the device; at least one second rectifying element including an anode connected to a second node of the device and a cathode connected to the first terminal; and at least one Zener diode or at least one Shockley diode series-connected with a capacitive element between the first and second nodes.

### CROSS-REFERENCE TO RELATED APPLICATION(S)

This application claims the priority benefit of French patent application number 23/04475, filed on May 4, 2023, entitled “Dispositif de protection contre des décharges électrostatiques”, which is hereby incorporated by reference to the maximum extent allowable by law.

### BACKGROUND

### Technical Field

The present disclosure generally concerns electronic devices, and more particularly devices of protection against electrostatic discharges.

### Description of the Related Art

Electrostatic discharges may generate, in integrated circuits or electronic components which are submitted thereto, harmful effects likely to cause an irreversible deterioration of all or part of their components. An integrated circuit or an electronic component may thus suffer from significant malfunctions, or even be made totally inoperative, as a result of an electrostatic discharge. In certain cases, a replacement of the defective circuit or component may result being necessary, thus adversely affecting the reliability of electronic appliances integrating such circuits or components.

To be protected against the harmful consequences of electrostatic discharges, integrated circuits and electronic components may include protection devices. However, existing devices of protection against electrostatic discharges suffer from various disadvantages. In particular, existing devices are poorly adapted to applications where they are supposed to both protect, against electrostatic discharges, a component or circuit biased by a voltage in the order of a few volts in nominal operation, and resist, in case of a short-circuit, to a voltage much higher than their nominal biasing, for example a DC voltage in the order of several tens of volts.

### BRIEF SUMMARY

There exists a need to improve existing devices of protection against electrostatic discharges. It would in particular be desirable to provide devices of protection against electrostatic discharges capable of better reconciling the aspects of resistance to short-circuits and of protection against electrostatic discharges.

For this purpose, an embodiment provides a device of protection against electrostatic discharges including:
at least one first rectifying element including an anode connected to a first terminal and a cathode connected to a first node of the device;
at least one second rectifying element including an anode connected to a second node of the device and a cathode connected to the first terminal; and
at least one Zener diode or at least one Shockley diode series-connected with a capacitive element between the first and second nodes.

According to an embodiment, the first and second rectifying elements are diodes.

According to an embodiment, the first and second rectifying elements each include a thyristor and a diode coupling an anode gate of the thyristor to a cathode of the thyristor.

According to an embodiment, the capacitive element is a capacitor.

According to an embodiment, the device includes a single first rectifying element and
a single second rectifying element, the device further including:
a third rectifying element including an anode connected to a second terminal and a cathode connected to the first node; and
a fourth rectifying element including an anode connected to the second node and a cathode connected to the second terminal.

According to an embodiment, the second terminal is a terminal of application of a reference potential.

According to an embodiment, the device includes at least two branches each including a single first rectifying element, a single second diode and a single first terminal distinct from the first rectifying elements, from the second rectifying elements, and from the first terminals of the other branches.

According to an embodiment, one of the first terminals is connected to the terminal of application of a reference potential.

According to an embodiment, said at least one Zener diode or at least one Shockley diode is a single Zener diode.

According to an embodiment, said Zener diode includes an anode connected to a third node and a cathode connected to the first node, the capacitive element including a first terminal connected to the third node and a second terminal connected to the second node.

According to an embodiment, said Zener diode includes an anode connected to the second node and a cathode connected to a third node, the capacitive element including a first terminal connected to the third node and a second terminal connected to the first node.

According to an embodiment, said at least one Zener diode or at least one Shockley diode is a single Shockley diode.

According to an embodiment, said at least one Zener diode or at least one Shockley diode includes at least two Zener diodes or at least two Shockley diodes.

According to an embodiment, the first and second terminals are intended to be connected to terminals of a connector, for example a Type-C USB connector.

An embodiment provides an electronic device, preferably smartphone, connected object, touch pad, or Type-C USB cable, including at least one device of protection against electrostatic discharges such as described.

According to an embodiment, a method includes receiving, a high supply voltage at a first terminal of an electrostatic discharge protection device. The first terminal is coupled to a cathode of a first rectifying element and to an anode of a second rectifying element. The method includes receiving a low supply voltage a second terminal of the electrostatic discharge device, the first terminal being coupled to a cathode of a third rectifying element and to an anode of a fourth rectifying element. The method includes receiving, between the first terminal and the second terminal, an overvoltage corresponding to a voltage difference higher than a difference between the high supply voltage and the low supply voltage under normal operating conditions. The method includes charging, during the overvoltage event, a capacitor via a first diode having an anode coupled to a first plate of the capacitor and a cathode coupled to cathodes of the second and fourth rectifying elements. The capacitor has a second terminal separated from the first terminal by a dielectric material and coupled to anodes of the first and third rectifying elements.

According to an embodiment, a device includes a first node, a second node, and a pair of first diodes coupled between the first node and the second node. The device includes a pair of second diodes coupled between the first node and the second node and a capacitor and a third diode coupled in series between the first node and the second node. The capacitor includes a first terminal coupled to the first node and a second terminal coupled to the third diode and separated from the first terminal by a dielectric material. The device includes a first voltage supply terminal coupled between the first diodes.

### BRIEF DESCRIPTION OF THE SEVERAL VIEWS OF THE DRAWINGS

The foregoing features and advantages, as well as others, will be described in detail in the rest of the disclosure of specific embodiments given by way of illustration and not limitation with reference to the accompanying drawings, in which:

FIG. 1 is an electric diagram illustrating an example of a usual device of protection against electrostatic discharges;

FIG. 2 is a current-vs.-voltage characteristic of the device of FIG. 1;

FIG. 3 is an electric diagram illustrating an example of a device of protection against electrostatic discharges according to an embodiment;

FIG. 4 is a current-vs.-voltage characteristic of the device of FIG. 3;

FIG. 5 is an electric diagram illustrating another example of a device of protection against electrostatic discharges according to an embodiment;

FIG. 6 is an electric diagram illustrating another example of a device of protection against electrostatic discharges according to an embodiment;

FIG. 7 is an electric diagram illustrating another example of a device of protection against electrostatic discharges according to an embodiment; and

FIG. 8 is an electric diagram illustrating another example of a device of protection against electrostatic discharges according to an embodiment.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for the understanding of the described embodiments have been illustrated and described in detail. In particular, the components or integrated circuits likely to be protected against electrostatic discharges by the devices of the present disclosure will not be described in detail, the described embodiments being compatible with components or integrated circuits usually protected against electrostatic discharges.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “edge”, “back”, “top”, “bottom”, “left”, “right”, etc., or relative positions, such as terms “above”, “under”, “upper”, “lower”, etc., or to terms qualifying directions, such as terms “horizontal”, “vertical”, etc., it is referred, unless specified otherwise, to the orientation of the drawings.

Unless specified otherwise, the expressions “about”, “approximately”, “substantially”, and “in the order of” signify plus or minus 10%, preferably of plus or minus 5%.

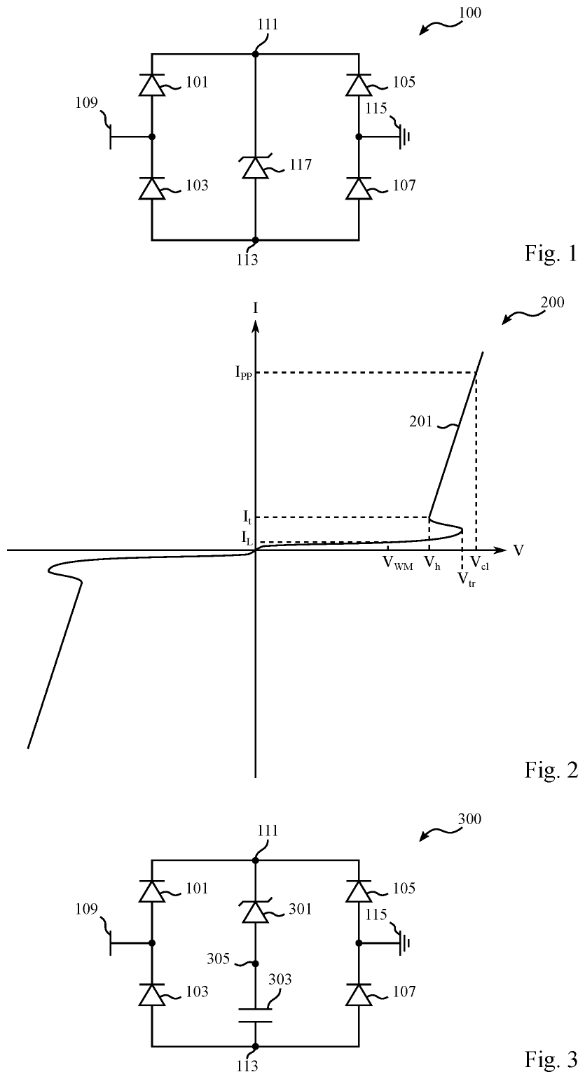

FIG. 1 is an electric diagram illustrating an example of a usual device 100 of protection against electrostatic discharges.

In the shown example, device 100 includes four diodes 101, 103, 105, and 107. More precisely, in the example illustrated in FIG. 1, diode 101 includes an anode electrode or terminal connected to a terminal 109 and a cathode electrode or terminal connected to an internal node 111 of device 100. In this example, diode 103 includes an anode electrode or terminal connected to another internal node 113 of device 100, distinct from internal node 111, and a cathode electrode or terminal connected to terminal 109. Further, diode 105 include an anode electrode or terminal connected to another terminal 115, distinct from terminal 109, and a cathode electrode or terminal connected to internal node 111, and diode 107 includes an anode electrode or terminal connected to internal node 113 and a cathode electrode or terminal connected to terminal 115.

The diodes 101, 103, 105, and 107 of device 100 are for example identical to one another, to within manufacturing dispersions. As an example, each diode 101, 103, 105, 107 exhibits a breakdown voltage in the order of 22 V.

Terminal 109 is for example intended to be connected to an input terminal, an output terminal, or an input-output terminal of a connector, of an integrated circuit, or of an electronic component to be protected against electrostatic discharges. Terminal 109 is for example adapted to being connected to a terminal for receiving and/or transmitting a digital or analog signal. In nominal operation, terminal 109 is for example submitted to a voltage lower than or equal to 5 V. As an example, terminal 109 is intended to be connected to a “SBU1”, “SBU2”, “CC1”, or “CC2” communication terminal or pin of a plug or of a socket of a Type-C USB connector (USB-C). The plug or the socket for example forms part of a cable or of an electronic device, for example a cell phone, a smartphone, a connected object, a touch pad, etc.

Terminal 115 is for example a terminal of application of a reference potential, for example the ground. As an example, in the case where terminal 109 is intended to be connected to a Type-C USB plug or socket, terminal 115 is intended to be connected to a ground terminal or pin “GND” of the plug or of the socket.

In the shown example, the device of protection against electrostatic discharges 100 further includes a diode 117, for example a Zener diode, coupling internal node 111 to internal node 113. More precisely, in the example illustrated in FIG. 1, diode 117 includes an anode electrode or terminal connected to internal node 113 and a cathode electrode or terminal connected to internal node 111.

The diode 117 of device 100 is for example sized so that it is in an off state, that is, non-conductive, when terminal 109 is submitted to its nominal operating voltage. Further, diode 117 is sized so that it is in the off state in case of a short-circuit. In the case where terminal 109 is intended to be connected to a terminal or pin forming part of a Type-C USB connector, such a short-circuit may for example occur between the terminal or pin to which is connected terminal 109 and a power supply terminal or pin “Vbus” adjacent to this terminal. As an example, in a case where terminal 109 is intended to be submitted to a nominal voltage lower than or equal to 5 V and is likely, in case of a short-circuit, to be submitted to a voltage in the range from 16 to 22 V, for example in the order of 20 V, diode 117 for example has a reverse voltage threshold equal to approximately 22 V.

In device 100, diodes 101, 103, 105, and 107 have a capacitance smaller, for example at least ten times smaller, than that of diode 117. This enables to “mask” the capacitance of diode 117, thus avoiding disturbing the signals present on terminal 109.

The operation of device 100 is discussed in further detail hereafter in relation with FIG. 2.

FIG. 2 is a current-vs.-voltage characteristic 200 of the device 100 of FIG. 1. The current-vs.-voltage characteristic of FIG. 2 more precisely includes a curve 201 illustrating variations of the intensity (I) of a current flowing through device 100 according to a bias voltage (V) applied between terminals 109 and 115. Curve 201 includes left-hand and right-hand portions respectively corresponding to the case where voltage V is negative and to the case where voltage V is positive. The left-hand and right-hand portions of curve 201 are for example substantially identical, in absolute value. For simplification, only the right-hand portion of curve 201 will be detailed hereafter, the transposition of the description to the left-hand portion of curve 201 being within the abilities of those skilled in the art based on the following indications.

In nominal operation or in case of a short-circuit, bias voltage V may for example take values in the range from 0 V to a limiting voltage V_{WM}. Limiting voltage V_{WM} for example corresponds to a maximum voltage value V provided for a given application. Limiting voltage V_{WM} is for example in the order of 20 V, in a case where the terminal 109 of device 100 is intended to be connected to a “SBU1”, “SBU2”, “CC1”, or “CC2” communication terminal forming part of a Type-C USB connector and where the voltage applied to the terminals “Vbus” of the connector, likely to form a short-circuit with terminal 109, is equal to approximately 20 V. When device 100 is biased under this limiting voltage V_{WM}, it conducts a low leakage current I_{L}.

In case of an overvoltage originating for example from an electrostatic discharge, bias voltage V may temporarily exceed a threshold voltage Vₜᵣ. Threshold voltage Vₜᵣ here corresponds to a voltage for triggering the protection. To avoid any risk of untimely triggering of this protection and any risk of irreversible deterioration in case of a short-circuit, device 100, in particular diode 117, is sized so that threshold voltage Vu is greater than the limiting voltage V_{WM} provided in the considered application.

In a case where threshold voltage Vₜᵣ is exceeded, that is, once the protection has been triggered for example due to an electrostatic discharge applying, between terminals 109 and 115, a voltage V greater than Vₜᵣ, voltage V slightly decreases to a hold voltage value Vₕ. Hold voltage Vₕ corresponds to the minimum voltage V that can be reached after the triggering of the protection. At hold voltage Vₕ, a current Iₜ greater than leakage current I_{L} flows through diode 117.

The electrostatic discharge may however be sufficiently significant for the bias voltage V of device 100 to keep on increasing even after the triggering of the protection. This increase of voltage V goes along with an increase of the current I crossing diode 117. The current I which crosses diode 117 is then substantially proportional to a difference between bias voltage V and hold voltage Vₕ according to a relation of the type I=(V−Vₕ)/R_{d}, where R_{d} is called dynamical resistance of the protection.

As illustrated in FIG. 1, the value of bias voltage V can then increase up to a value V_{cl} called clamping voltage. Voltage V_{cl} corresponds to a maximum current I_{PP} acceptable by the protection (“peak pulse current”).

A disadvantage of device 100 lies in the fact that, to enable to dissipate electrostatic discharges while being capable to resist to short-circuits, diode 117 has a trigger voltage Vₜᵣ much higher, for example in the order of ten times higher, than the nominal voltage of terminal 109 in the absence of a short-circuit. This adversely affects the dissipation of electrostatic discharges by device 100 since the voltage applied between terminals 109 and 115 in case of electrostatic discharge increases from a value of hold voltage Vₕ also in the order of ten times higher than the nominal voltage. As a result, the circuit(s) and/or component(s) protected by device 100 may be submitted to high voltages V, for example in the order of 25 V, in case of electrostatic discharge, which is likely to damage them.

FIG. 3 is an electric diagram illustrating an example of a device 300 of protection against electrostatic discharges according to an embodiment.

The device 300 of FIG. 3 includes elements common with the device 100 of FIG. 1. These common elements will not be detailed again hereafter. The device 300 of FIG. 3 differs from the device 100 of FIG. 1 in that device 300 includes a diode 301, for example a Zener diode, and a capacitive element 303 in series between internal nodes 111 and 113. In the shown example, diode 301 and capacitive element 303 are series-connected between node 111 and node 113. More precisely, in the example illustrated in FIG. 3, diode 301 include an anode electrode or terminal connected to another internal node 305, distinct from nodes 113 and 111, and a cathode electrode or terminal connected to internal node 111. Capacitive element 303 includes an electrode or terminal connected to internal node 305 and another electrode or terminal connected to internal node 113.

The diode 301 of device 300 is for example similar to the diode 117 of device 100, but differs from diode 117 in that it has a triggering voltage lower, for example approximately four times lower, than that of 117. As an example, diode 301 exhibits a triggering voltage or reverse voltage in the order of 5 V, in absolute value, in a case where the nominal voltage applied between terminals 109 and 115 is lower than or equal to 5 V, in absolute value.

Further, FIG. 3 illustrates an example where diode 301 couples node 111 to node 305 and where capacitive element 303 couples node 305 to node 113. This example is however not limiting, and the positions of diode 301 and of capacitive element 303 in device 300 may, as a variant, be exchanged, so that diode 301 couples node 305 to node 113, the anode and the cathode of diode 301 then being respectively connected to nodes 113 and 305, and so that capacitive element 303 couples node 111 to node 305.

The capacitive element 303 of device 300 is more precisely a capacitor including two electrically-conductive electrodes or plates, for example two metal electrodes parallel to each other, separated from one another by a dielectric material. As an example, device 300 may be totally or partly formed based on discrete components. Device 300 for example has a monolithic structure except for capacitive element 303, formed by a discrete component. This for example advantageously enables to use device 300 provided either with capacitive element 303, for example in a case where terminal 109 is likely to be submitted to a short-circuit, or with a conductive track substituted to capacitive element 303, for example in a case where terminal 109 is not intended to be able to be submitted to a short-circuit. As a variant, device 300 may have a totally monolithic structure, that is, a structure having fully integrated elements, capacitive element 303 then for example being a capacitor of MIM (“Metal Insulator Metal”) type formed in a stack of electrically-conductive levels, for example metal layers, separated from one another by electrically-insulating levels, for example dielectric layers.

As an example, capacitive element 303 has a capacitance in the range from 100 nF to 10 μF.

Although this has not been detailed in FIG. 3, device 300 may further include a component or a circuit for discharging capacitive element 303, for example a resistor associated in parallel with capacitive element 303. As a variant, means for discharging the capacitive element 303 of device 300 may include a transistor, for example a MOS (“Metal-Oxide-Semiconductor”) transistor, having a conduction terminal, for example a drain electrode, connected to node 305, having another conduction terminal, for example a source electrode, connected to terminal 113 and having a control terminal, for example a gate electrode, connected to a control circuit.

FIG. 4 is a current-vs.-voltage characteristic of the device 300 of FIG. 3. The current-vs.-voltage characteristic of FIG. 4 more precisely includes a curve 401 illustrating variations of the intensity (I) of a current flowing through device 300 according to a bias voltage (V) applied between terminals 109 and 115 of device 300. Curve 401 illustrates a “dynamic” operation of device 300, that is, when device 300 is submitted to an electrostatic discharge, capacitive element 303 then behaving as a short-circuit, while, in “static” operation, that is, in the absence of an electrostatic discharge, capacitive element 303 behaves as an open circuit and the current-vs.-voltage characteristic of device 300 then exhibits a shape different from that of curve 401. Curve 401 includes left-hand and right-hand portions respectively corresponding to the case where voltage V is negative and to the case where voltage V is positive. The left-hand and right-hand portions of curve 401 are for example substantially identical, in absolute value. For simplification, only the right-hand portion of curve 401 will be detailed hereafter, the transposition of the description to the left-hand portion of curve 401 being within the abilities of those skilled in the art based on the following indications. To highlight the differences between the device 100 of FIG. 1 and the device 300 of FIG. 3, curve 201 has been shown in FIG. 4 as a comparison. Conversely to curve 401, which only illustrates the dynamic operation of device 300, curve 201 for example illustrates both the static operation and the dynamic operation of device 100.

The device 300 of FIG. 3 exhibits a threshold voltage V′ₜᵣ lower, for example at least twice lower, for example approximately five times lower, than the threshold voltage Vₜᵣ of the device 100 of FIG. 1. This enables device 300 to dissipate electrostatic discharges more efficiently than device 100, since the voltage V applied between terminals 109 and 115 of device 300 in case of an electrostatic discharge increases from a value lower than in the case of device 100, for example a value in the order of the nominal voltage applied to terminal 109. Further, device 300 exhibits a dynamic resistance Ra smaller than that of device 100, which enables device 300 to achieve a higher performance in terms of dissipation of electrostatic discharges than device 100, particularly a lower voltage V, for a same value of current I.

In case of a short-circuit resulting for example from the application, to terminal 109, of a DC voltage higher than the nominal voltage, a current starts by flowing between terminal 109 and terminal 115, through diode 101, diode 301, capacitive element 303, and diode 107. Once capacitive element 303 has been charged, it then behaves as an open circuit and the current flow is interrupted. This advantageously enables to avoid any irreversible degradation of diode 301 in case of a short-circuit.

An advantage of device 300 thus lies in the fact that it enables to dissipate electrostatic discharges more efficiently than device 100, while remaining protected against short-circuits.

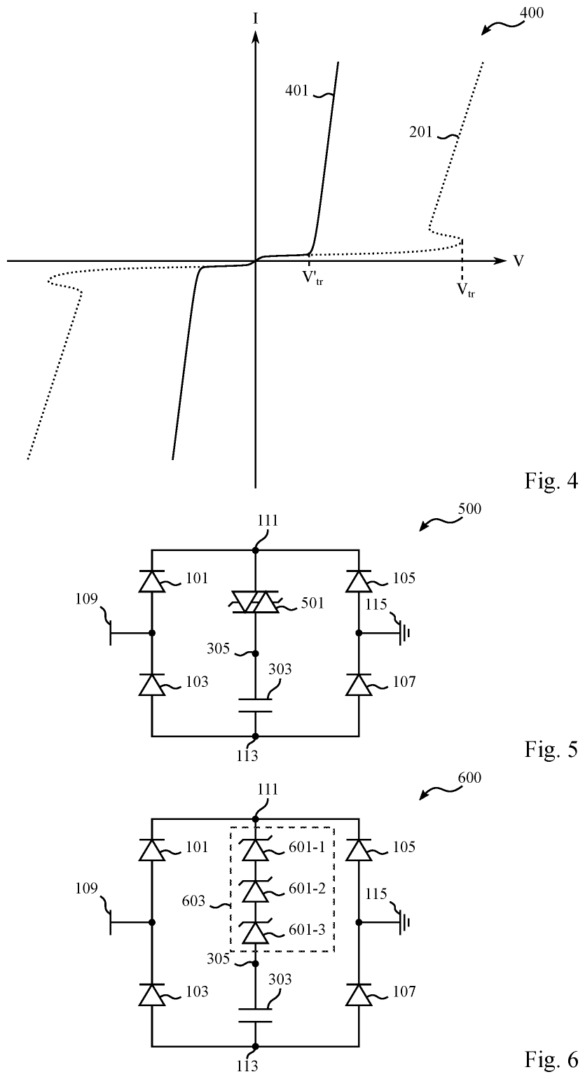

FIG. 5 is an electric diagram illustrating another example of a device 500 of protection against electrostatic discharges according to an embodiment. The device 500 of FIG. 5 includes elements common with the device 300 of FIG. 3. These common elements will not be detailed again hereafter. The device 500 of FIG. 5 differs from the device 300 of FIG. 3 in that device 500 includes a breakover diode 501, also called Shockley diode, coupling internal node 111 to internal node 305.

The voltage V applied between the terminals 109 and 115 of device 500 in case of an electrostatic discharge increases from a value still lower than in the case of device 300, for example a substantially zero value. This advantageously enables device 500 to achieve a performance in terms of protection against electrostatic discharges still higher than that of device 300.

As an example, for a current I equal to approximately 16 A corresponding for example to an electrostatic discharge in the order of 8 kV on terminal 109, the voltage V between the terminals 109 and 115 of device 500 is equal to approximately 13 V.

FIG. 6 is an electric diagram illustrating another example of a device 600 of protection against electrostatic discharges according to an embodiment. The device 600 of FIG. 6 includes elements common with the device 300 of FIG. 3. These common elements will not be detailed again hereafter. The device 600 of FIG. 6 differs from the device 300 of FIG. 3 in that device 600 includes a plurality of diodes 601 in series between internal nodes 305 and 111. More precisely, in the example illustrated in FIG. 6, device 600 includes three diodes 601-1, 601-2, and 601-3, for example Zener diodes, associated in series between node 305 and node 111. In this example, diode 601-1 includes an anode electrode or terminal connected to a cathode electrode or terminal of diode 601-2, and a cathode electrode or terminal connected to node 111. Further, diode 601-2 includes an anode electrode or terminal connected to a cathode electrode or terminal of diode 601-3, and diode 601-3 includes an anode electrode or terminal connected to node 305. Although FIG. 6 illustrates an example where device 600 includes a group 603 of three diodes 601-1, 601-2, and 601-3, group 603 may of course include any number, greater than or equal to two, of diodes coupling node 305 to node 111.

In device 600, each diode 601-1, 601-2, 601-3 is submitted, between its terminals, to a voltage substantially equal to one third of the voltage applied between the terminals of diode 301 of device 300. In other words, the voltage applied between nodes 111 and 305 is distributed between diodes 601-1, 601-2, and 601-3. This advantageously enables device 600 to reach more significant clamping voltages V_{cl} than device 300, for example in cases where it would be desirable to obtain a voltage Vcl higher than that which would be obtained by using a single diode, for example diode 301 of device 300. This further enables to decrease the voltage across each diode 601-1, 601-2, 601-3 of device 600 with respect to the voltage across diode 301 of device 300, and thus to attenuate disadvantages due to a capacitance variation of the diodes according to the voltage applied thereacross. This results, for example, in device 600, in a decrease of the intensity of the harmonics, particularly of odd harmonics, more particularly of the harmonic of rank 3 (H3), with respect to device 300.

FIG. 7 is an electric diagram illustrating another example of device 700 of protection against electrostatic discharges according to an embodiment. The device 700 of FIG. 7 includes elements common with the device 300 of FIG. 3. These common elements will not be detailed again hereafter. The device 700 of FIG. 7 differs from the device 300 of FIG. 3 in that device 700 does not include diodes 105 and 107 and in that device 700 includes a plurality of terminals 109 (four terminals 109-1, 109-2, 109-3, and 109-4, in the illustrated example), each connected between two diodes 103 and 101 in series. One of the terminals 109 of device 700 (terminal 109-4, in the illustrated example) is connected to the node 115 of application of the reference potential.

More precisely, in the shown example, device 700 includes a plurality of branches 701 (four branches 701, in the illustrated example), each including the terminal 109 (109-1, 109-2, 109-3, or 109-4) connected to the anode of diode 101 (101-1, 101-2, 101-3, or 101-4) and to the cathode of diode 103 (103-1, 103-2, 103-3, or 103-4), the anode of diode 103 being connected to internal node 113 and the cathode of diode 101 being connected to internal node 111. Although FIG. 7 illustrates an example where device 700 includes four branches 701, device 700 may, as a variant, include any number, greater than or equal to two, of branches 701. In the illustrated example, the diode 101, the diode 103, and the terminal 109 of each branch 701 are distinct from the diode 101, from the diode 103, and from the terminal 109 of the other branches 701 of device 700.

As an example, terminals 109-1, 109-2, 109-3, and 109-4 are intended to be connected to distinct terminals or pins of a Type-C USB connector.

Device 700 has an operation and advantages similar to those of the device 300 of FIG. 3. An additional advantage of device 700 lies in the fact that device 700 enables to share diode 301 and capacitive element 303 for a plurality of terminals 109. This thus enables device 700 to have a complexity, a cost, and a bulk lower than those which would be obtained by using one device 300 for each terminal 109 (109-1, 109-2, 109-3, and 109-4) to be protected.

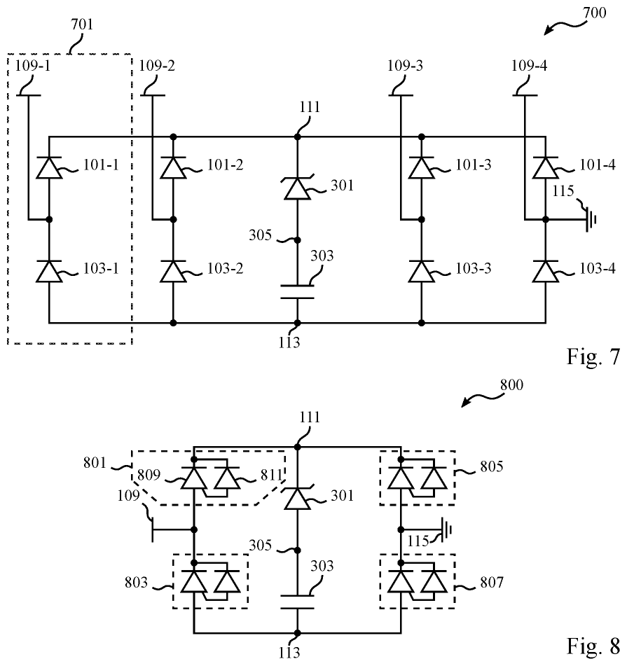

FIG. 8 is an electric diagram illustrating another example of a device 800 of protection against electrostatic discharges according to an embodiment. The device 800 of FIG. 8 includes elements common with the device 300 of FIG. 3. These common elements will not be detailed again hereafter. The device 800 of FIG. 8 differs from the device 300 of FIG. 3 in that the rectifying elements, formed by diodes 101, 103, 105, and 107 in the case of device 300, are, in the case of device 800, respectively replaced with assemblies 801, 803, 805, and 807, each including a thyristor 809 and a diode 811. In each assembly 801, 803, 805, 807, thyristor 809 includes an anode gate coupled, by diode 811, to a cathode electrode or terminal of thyristor 809. More precisely, diode 811 includes an anode electrode or terminal connected to the anode gate of thyristor 809, and a cathode electrode or terminal connected to the cathode electrode or terminal of thyristor 809.

Each assembly 801, 803, 805, 807 includes an anode electrode or terminal corresponding to an anode electrode or terminal of thyristor 809 and a cathode electrode or terminal corresponding to the cathode electrode or terminal of thyristor 809. What has been previously described in relation with the electrodes or anode and cathode terminals of the diodes 101, 103, 105, and 107 of the device 300 of FIG. 3, in particular the connections of these electrodes or terminals to the other terminals and nodes of device 300, is transposable by those skilled in the art to the electrodes or anode and cathode of the assemblies 801, 803, 805, and 807, respectively, of the device 800 of FIG. 8.

Various embodiments and variants have been described. Those skilled in the art will understand that certain features of these various embodiments and variants may be combined, and other variants will occur to those skilled in the art. In particular:
the embodiments of devices 500 and 600 may be combined, all or part of the diodes 601-1, 601-2, and 601-3 of device 600 then being replaced with a breakover diode similar to the diode 501 of device 500;
the embodiments of devices 500 and 700 may be combined, the diode 301 of device 700 for example then being replaced with a breakover diode similar or identical to the diode 501 of device 500; and
the embodiments of devices 600 and 700 may be combined, and possibly combined with the embodiment of device 500, the diode 301 of device 700 then being for example replaced with a group 603 including a plurality of diodes similar or identical to the diodes 601-1, 601-2, and 601-3 of device 600 or with a group similar to group 603 but including a plurality of breakover diodes for example similar to the diode 501 of device 500.

Further, the embodiment of device 800 may be combined with each of the embodiments of devices 500, 600, and 700, where each diode 101, 103, 105, 107 of these devices may be replaced with an assembly identical to assemblies 801, 803, 805 and 807, that is, with a rectifying element including a thyristor 809 having its anode gate coupled to its cathode electrode or terminal by a diode 811.

Although bidirectional protection devices 300, 500, 600, 700, and 800, capable of indifferently dissipating positives or negative overvoltages, have been described hereabove in relation with FIGS. 3, 5, 6, 7, and 8, it would be possible, based on the indications of the present disclosure, to form unidirectional protection devices, capable of only dissipating positive or negative overvoltages. Such devices may for example be obtained by connecting the terminal 115 of application of the reference potential to node 113 rather than to node 109 in each of devices 300, 500, 600, 700, and 800.

Finally, the practical implementation of the described embodiments and variants is within the abilities of those skilled in the art based on the functional indications given hereabove. In particular, those skilled in the art are capable of providing means for discharging capacitive element 303 based on the indications of the present disclosure.

Those skilled in the art are further capable of determining the values of the threshold voltages of diodes 101, 103, 105, 107, 117, 301, 501, 601-1, 601-2, and 601-3 and the capacitance of capacitive element 303 according to the application, for example by means of digital simulation tools.

Further, although the present disclosure details examples of application where terminals 109 and 115 correspond to terminals or pins of a Type-C USB connector, the described embodiments are not limited to this application but may be implemented in any type of electronic device, component, circuit, etc., likely to be protected against electrostatic discharges and to be submitted to short-circuits.

Finally, the positions of capacitive element 303 one the one part, and of breakover diode 501, of the group 603 of diodes 601 or of diode 301 on the other hand, may be exchanged in protection devices 500, 600, and 700, respectively.

A device (300; 500; 600; 700; 800) of protection against electrostatic discharges including: at least one first rectifying element (101; 101-1, 101-2, 101-3, 101-4; 801) including an anode connected to a first terminal (109; 109-1, 109-2, 109-3, 109-4) and a cathode connected to a first node (111) of the device; at least one second rectifying element (103; 103-1, 103-2, 103-3, 103-4) including an anode connected to a second node (113) of the device and a cathode connected to the first terminal (109); and at least one Zener diode (301; 601-1, 601-2, 601-3) or at least one Shockley diode (501) series-connected with a capacitive element (303) between the first and second nodes (111, 113).

The first and second rectifying elements (101, 103) are diodes.

The first and second rectifying elements (801, 803) each include a thyristor (809) and a diode (811) coupling an anode gate of the thyristor to a cathode of the thyristor.

The capacitive element (303) is a capacitor.

Device (300; 500; 600; 800) including a single first rectifying element (101; 801) and a single second rectifying element (103; 803), the device further including: a third rectifying element (105; 805) including an anode connected to a second terminal (115) and a cathode connected to the first node (111); and a fourth rectifying element (107; 807) including an anode connected to the second node (113) and a cathode connected to the second terminal (115).

The second terminal (115) is a terminal of application of a reference potential.

Device (700) including at least two branches (701) each including a single first rectifying element (101-1, 101-2, 101-3, 101-4; 801), a single second diode (103-1, 103-2, 103-3, 103-4; 803), and a single first terminal (109-1, 109-2, 109-3, 109-4) distinct from the first rectifying elements, from the second rectifying elements, and from the terminals of the other branches.

One of the first terminals (109-1, 109-2, 109-3, 109-4) is connected to a third terminal (115) of application of a reference potential.

Said at least one Zener diode or at least one Shockley diode is a single Zener diode (301).

Said Zener diode (301) includes an anode connected to a third node (305) and a cathode connected to the first node (111), the capacitive element (303) including a first terminal connected to the third node (305) and a second terminal connected to the second node (113).

Said Zener diode (301) includes an anode connected to the second node (113) and a cathode connected to a third node (305), the capacitive element (303) including a first terminal connected to the third node (305) and a second terminal connected to the first node (111).

Said at least one Zener diode or at least one Shockley diode is a single Shockley diode (501).

Said at least one Zener diode or at least one Shockley diode includes at least two diodes Zener or at least two Shockley diodes.

The first and second terminals (109, 115) are intended to be connected to terminals of a connector, for example a Type-C USB connector.

Electronic device, preferably smartphone, connected object, touch pad, or Type-C USB cable, including at least one device (300; 500; 600; 700; 800) of protection against electrostatic discharges.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A device, comprising:
a first node;
a second node;
one or more first terminals;
at least one first rectifying element including an anode connected to the first terminal and a cathode connected to the first node;
at least one second rectifying element including an anode connected to the second node and a cathode connected to the at least one first terminal; and
at least one Zener diode or at least one Shockley diode series-connected with a capacitive element between the first and second nodes, wherein the capacitive element is a capacitor comprising a first electrically conductive electrode and a second electrically conductive electrode separated from the first electrically conductive electrode by a dielectric material.

2. The device according to claim 1, wherein the first and second rectifying elements are diodes.

3. The device according to claim 1, wherein the first and second rectifying elements each include a thyristor and a diode coupling an anode gate of the thyristor to a cathode of the thyristor.

4. The device according to claim 1, comprising:
a second terminal;
a single first rectifying element;
a single second rectifying element;
a third rectifying element including an anode connected to the second terminal and a cathode connected to the first node; and
a fourth rectifying element including an anode connected to the second node and a cathode connected to the second terminal.

5. The device according to claim 4, wherein the second terminal is a terminal of application of a reference potential.

6. The device according to claim 1, comprising at least two branches each including a single first rectifying element, a single second diode, and a single first terminal distinct from the first rectifying elements, from the second rectifying elements, and from the terminals of the other branches.

7. The device according to claim 6, comprising a third terminal of application of a reference potential, wherein one of the first terminals is connected to the third terminal.

8. The device according to claim 1, wherein the at least one Zener diode or at least one Shockley diode is a single Zener diode.

9. The device according to claim 8, comprising a third node, wherein the Zener diode includes an anode connected to the third node and a cathode connected to the first node, the capacitive element including a first terminal connected to the third node and a second terminal connected to the second node.

10. The device according to claim 8, wherein the Zener diode includes an anode connected to the second node and a cathode connected to a third node, the capacitive element including a first terminal connected to the third node and a second terminal connected to the first node.

11. The device according to claim 1, wherein the at least one Zener diode or at least one Shockley diode is a single Shockley diode.

12. The device according to claim 1, wherein the at least one Zener diode or at least one Shockley diode includes at least two diodes Zener or at least two Shockley diodes.

13. The device according to claim 1, wherein the first and second terminals are configured to be connected to terminals of a Type-C USB connector.

14. The device of claim 1, comprising a smartphone, a connected object, a touch pad, or a Type-C USB cable.

15. A method, comprising:
receiving, a high supply voltage at a first terminal of an electrostatic discharge protection device, the first terminal being coupled to a cathode of a first rectifying element and to an anode of a second rectifying element;
receiving a low supply voltage a second terminal of the electrostatic discharge device, the first terminal being coupled to a cathode of a third rectifying element and to an anode of a fourth rectifying element;
receiving, between the first terminal and the second terminal, an overvoltage corresponding to a voltage difference higher than a difference between the high supply voltage and the low supply voltage under normal operating conditions; and
charging, during the overvoltage event, a capacitor via a first diode having an anode coupled to a first plate of the capacitor and a cathode coupled to cathodes of the second and fourth rectifying elements, the capacitor having a second terminal separated from the first terminal by a dielectric material and coupled to anodes of the first and third rectifying elements.

16. The method of claim 14, wherein the first diode is a Zener diode or a Schottky diode.

17. The method of claim 15, wherein the first diode has a reverse triggering voltage less than double the difference between the high supply voltage and the low supply voltage under normal operating conditions.

18. A device, comprising:
a first node;
a second node;
a pair of first diodes coupled between the first node and the second node;
a pair of second diodes coupled between the first node and the second node;
a capacitor and a third diode coupled in series between the first node and the second node, wherein the capacitor includes a first terminal coupled to the first node and a second terminal coupled to the third diode and separated from the first terminal by a dielectric material; and
a first voltage supply terminal coupled between the first diodes.

19. The device of claim 18, wherein the first diode is a Zener diode.

20. The device of claim 18, wherein the third diode is a Schottky diode.
